(19) United States
(12) Patent Application Publication
(10) Pub. No.: US 2008/0182372 A1
(43) Pub. Date: Jul. 31, 2008

(54) METHOD OF FORMING DISPOSABLE SPACERS FOR IMPROVED STRESSED NITRIDE FILM EFFECTIVENESS

(75) Inventors: Joyce C. Liu, Carmel, NY (US); Hongwen Yan, Somers, NY (US); Qingyun Yang, Poughkeepsie, NY (US); Ying Zhang, Yorktown Heights, NY (US)

Correspondence Address: CANTOR COLBURN LLP-IBM YORKTOWN, 20 Church Street, 22nd Floor, Hartford, CT, 06103, US

(73) Assignee: International Business Machines Corporation, Armonk, NY (US)

(21) Appl. No.: 11/669,645

(22) Filed: Jan. 31, 2007

(51) Int. Cl. H01L 21/8238

(52) U.S. Cl. 438/230; 257/E21.632

(57) ABSTRACT

A method of forming a complementary metal oxide semiconductor (CMOS) device includes forming an oxide layer on sidewalls and a top surface of a patterned gate conductor, and on sidewalls of a gate insulating layer formed on a semiconductor substrate; forming a first carbon-based layer over the gate conductor, gate insulating layer, and substrate; etching the first carbon-based layer so as to create a first set of carbon spacers; forming a second carbon-based layer over the gate conductor, gate insulating layer, substrate, and first set of carbon spacers; etching the second carbon-based layer so as to create a second set of carbon spacers; forming silicide contacts on the gate conductor, and on source and drain regions formed in the substrate; removing the first and second sets of carbon spacers; and forming a stress-inducing nitride layer over the substrate, silicide contacts, gate conductor, and gate insulating layer.

### BACKGROUND

The present invention relates generally to semiconductor device processing techniques, and, more particularly, to a method of forming disposable spacers for improved stressed nitride film effectiveness in complementary metal oxide semiconductor (CMOS) devices.

Strain engineering techniques have recently been applied to CMOS device manufacturing in order to provide different stresses in P-type MOS (PMOS) devices with respect to N-type MOS (NMOS) devices. For example, a nitride liner of a first type is formed over the PFETs of a CMOS device, while a nitride liner of a second type is formed over the NFETs of the CMOS device. More specifically, it has been discovered that the application of a compressive stress in a PFET channel improves carrier (hole) mobility therein, while the application of a tensile stress in an NFET channel improves carrier (electron) mobility therein, leading to higher on-current and product speed. Thus, the first type nitride liner over the PFET devices is formed in a manner so as to achieve a compressive stress, while the second type nitride liner over the NFET devices is formed in a manner so as to achieve a tensile stress. Conversely, device performance may be reduced when stresses of the opposite type are respectively applied to NFET and PFET devices.

For such CMOS devices employing compressive/tensile liners, the presence of conventional nitride spacers formed on gate sidewalls (used for deep source/drain region dopant implantation) has tended to reduce the effectiveness of the subsequently formed tensile/compressive liners. Alternatively, the nitride spacers can be removed subsequent to gate/source/drain contact silicidation, and prior to stress liner formation. However, the existing nitride spacer removal processes (e.g., wet etching in hot phosphoric acid or dry etching in F—, Cl— or Br— containing plasmas) attack doped silicon (particularly n+doped silicon), beneath the silicide contacts on top of the gates and the extension areas between the gates and silicide contacts of the source drain regions, as depicted by the scanning electron micrograph (SEM) view of FIG. 1.

Accordingly, it would be desirable to be able to improve the effectiveness of tensile/compressive nitride layers in CMOS devices without the drawbacks associated with conventional nitride spacer removal techniques.

### SUMMARY

The foregoing discussed drawbacks and deficiencies of the prior art are overcome or alleviated by, in an exemplary embodiment, a method of forming a complementary metal oxide semiconductor (CMOS) device, including forming an oxide layer on sidewalls and a top surface of a patterned gate conductor, and on sidewalls of a gate insulating layer formed on a semiconductor substrate; forming a first carbon-based layer over the gate conductor, gate insulating layer, and substrate; etching the first carbon-based layer so as to create a first set of carbon spacers; forming a second carbon-based layer over the gate conductor, gate insulating layer, substrate, and first set of carbon spacers; etching the second carbon-based layer so as to create a second set of carbon spacers; forming silicide contacts on the gate conductor, and on source and drain regions formed in the substrate; removing the first and second sets of carbon spacers; and forming a stress-inducing nitride layer over the substrate, silicide contacts, gate conductor, and gate insulating layer.

In another embodiment, a method of forming a complementary metal oxide semiconductor (CMOS) device includes forming a patterned gate conductor and gate insulating layer on a semiconductor substrate; forming an oxide layer on sidewalls and a top surface of the gate conductor, on sidewalls of the gate insulating layer, and on the substrate; depositing a first amorphous carbon layer over the gate conductor, gate insulating layer, and oxide layer; anisotropically etching the first carbon-based layer so as to create a first set of amorphous carbon spacers; implanting source and drain extensions in the substrate following the formation of the first set of amorphous carbon spacers; forming a second amorphous carbon layer over the gate conductor, gate insulating layer, oxide layer, and first set of amorphous carbon spacers; anisotropically etching the second amorphous carbon layer so as to create a second set of amorphous carbon spacers adjacent the first set of amorphous carbon spacers; removing remaining exposed portions of the oxide layer from the substrate and the top surface of the gate conductor; implanting source and drain regions in the substrate; forming silicide contacts on the gate conductor, and the source and drain regions formed in the substrate; isotropically etching and removing the first and second sets of amorphous carbon spacers; and forming a stress-inducing nitride layer over the substrate, silicide contacts, gate conductor, and gate insulating layer.

### BRIEF DESCRIPTION OF THE DRAWINGS

Referring to the exemplary drawings wherein like elements are numbered alike in the several Figures:

FIG. 1 is a scanning electron micrograph (SEM) view of a CMOS device, illustrating regions of attached silicon due to nitride spacer etching; and

FIGS. 2(a) through 2(j) are a series of cross-sectional views illustrating a method of forming disposable spacers for improved stressed nitride film effectiveness in complementary metal oxide semiconductor (CMOS) devices, in accordance with an embodiment of the invention.

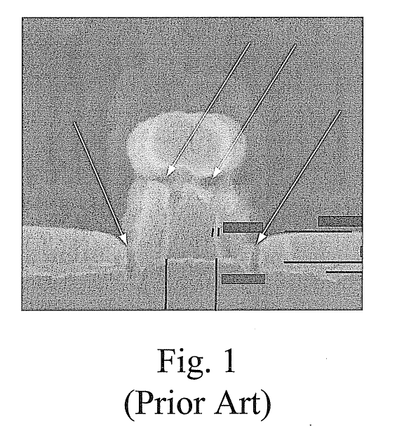

### DETAILED DESCRIPTION

Disclosed herein is a method of forming disposable spacers for improved stressed nitride film effectiveness in complementary metal oxide semiconductor (CMOS) devices. Briefly stated, the traditional nitride spacers are replaced by first and second sacrificial spacers, made of a carbon based material such as amorphous carbon. The carbon material spacers are integrated into the same dopant implantation/fabrication scheme as before; however, the carbon based spacers may be removed through a plasma etch process that has a high selectivity to silicon beneath the silicided gate, source and drain regions. As a result, the effectiveness of a subsequently formed tensile/compressive nitride layer is not hampered by gate spacers used for extension and deep source drain implant steps.

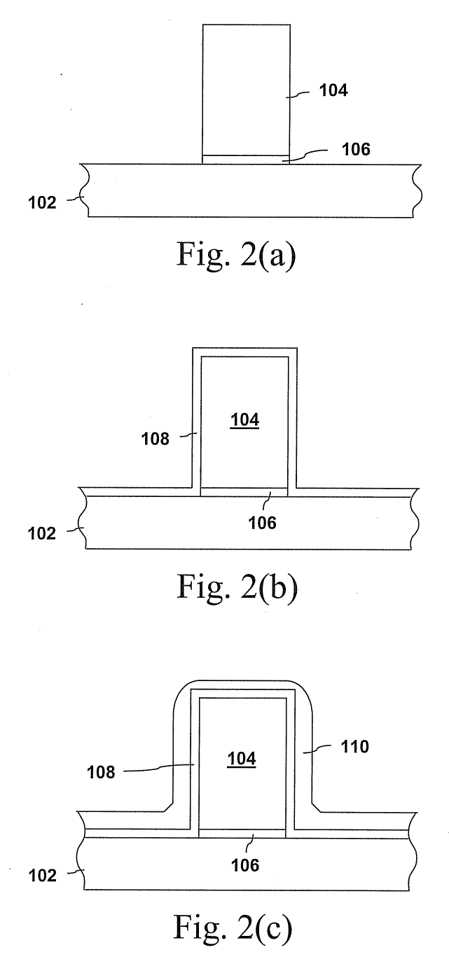

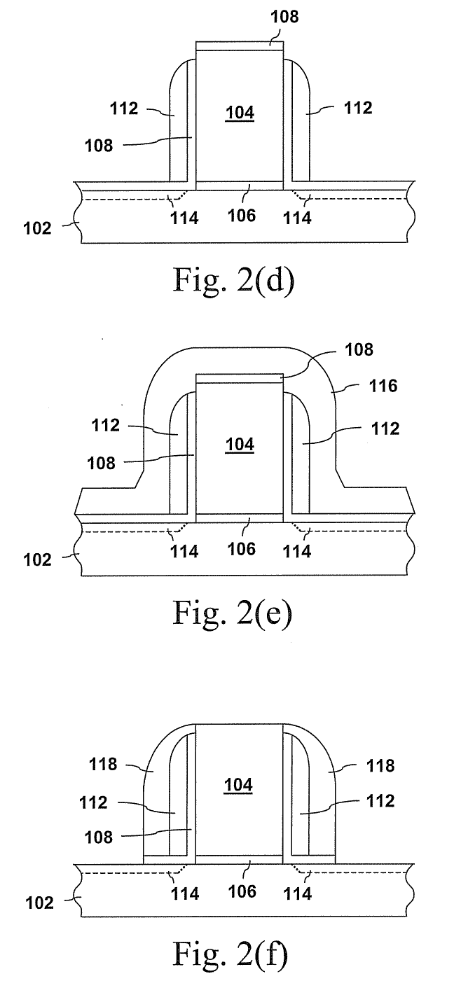

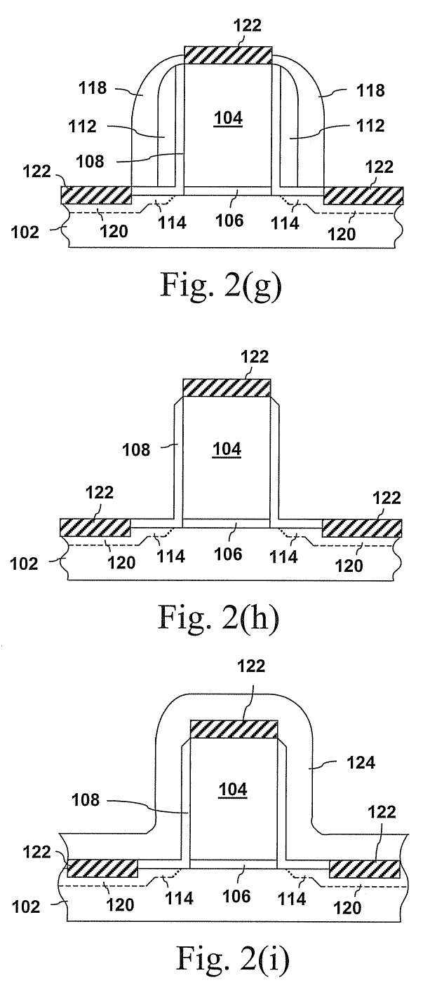

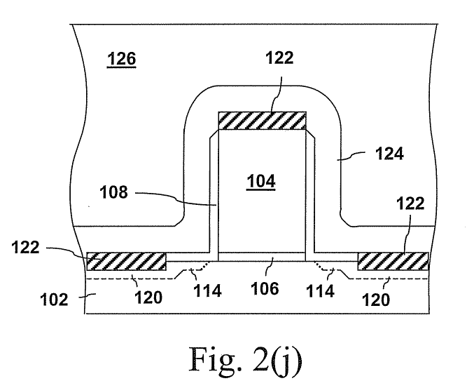

Referring generally to FIGS. 2(a) through 2(j), there is shown a series of cross-sectional views illustrating a method of forming disposable spacers for improved stressed nitride film effectiveness in complementary metal oxide semiconductor (CMOS) devices, in accordance with an embodiment of the invention.

FIG. 2(a) illustrates a point in CMOS processing following the patterning of a gate electrode 104 (e.g., polysilicon) and a gate insulating or dielectric layer 106 (e.g., an oxide or nitride of silicon) on a substrate 102 (e.g., silicon, silicon-on-insulator or “SOI”). In FIG. 2(b), a protective oxide layer 108 is formed on the substrate 102, sidewalls of the gate insulating layer 106, and the sidewalls and top surface of the gate conductor 104 prior to source/drain extension implantation. The oxide layer 108 may be formed by techniques such as annealing, oxide deposition or a wet chemical oxide process, for example. As will be seen herein after, the oxide layer 108 protects the substrate from a subsequent carbon removal process.

In lieu of a nitride spacer formation, FIG. 2(c) illustrates the formation of a first carbon-based layer 110, such as amorphous carbon, over the oxide layer 108. Then, as shown in FIG. 2(d), a first set of carbon-based sidewall spacers 112 are formed from the carbon-based layer 110, by a suitable anisotropic technique such as reactive ion etching (RIE), for example. Following RIE, the first set of sidewall spacers 112 and sidewall oxide layer 108 may be recessed from a topmost portion of the gate conductor 104. As also illustrated in FIG. 2(d), a first ion implantation (I/I) is used to define the source and drain extensions 114, the location of which is determined by the thickness of the first set of carbon-based sidewall spacers 112.

Then, as shown in FIG. 2(e), a second carbon-based layer 116, such as amorphous carbon, is formed over the structure of FIG. 2(d). In addition to serving as a spacer material for a subsequent deep source/drain region implantation, the second carbon-based layer 116 provides additional protection of the top most portions of the gate conductor and subsequent silicide contact thereon during the final removal of carbon material. As with the first carbon-based layer, the second carbon-based layer 116 is anisotropically etched (e.g., by RIE) as shown in FIG. 2(f) so as to create a second set of carbon-based sidewall spacers 118 adjacent the first set of carbon based sidewall spacers 114. In addition, the remaining exposed portions of the oxide layer 108 are also removed in preparation of the deep source/drain implantation.

Both the deep source/drain regions 120 and the subsequent silicide contact 122 formation are illustrated in FIG. 2(g). Once the deep source/drain regions 120 are implanted with a suitable dopant material, the silicide contacts 122 are formed by a blanket deposition of a refractory metal (e.g., nickel, cobalt, tantalum, titanium, etc.) followed by an annealing step to react the metal with silicon. As is known in the art, this process is a self-aligning (“salicide”) process, such that unreacted metal may be selectively removed to leave the silicide contacts 122, which provide good ohmic contact for the gate, source and drain electrodes of the CMOS transistor.

After silicide contact formation, both sets of carbon based spacers are removed through a selective isotropic etch process that, contrary to nitride removal processes, does not attack vulnerable regions of silicon (e.g., regions beneath and adjacent to the silicide contacts 122 as described above). The carbon spacer removal is illustrated in FIG. 2(h). Then, as shown in FIG. 2(i), a stress-inducing (tensile or compressive, depending on the device polarity) layer 124 (e.g., nitride) is deposited over the structure to improve carrier mobility (e.g., electrons or holes) in the device channel as known in the art. As a result of the removal of carbon-based spacers 114, 118 beforehand, the effectiveness of the nitride layer 124 is enhanced.

Finally, as shown in FIG. 2(j), an interlevel dielectric layer 126 is formed over the structure, in which conductive vias and first level wiring (not shown) are formed to provide electrical connection between the FET and other transistors and components of the CMOS device, as well as to upper wiring levels.

While the invention has been described with reference to a preferred embodiment or embodiments, it will be understood by those skilled in the art that various changes may be made and equivalents may be substituted for elements thereof without departing from the scope of the invention. In addition, many modifications may be made to adapt a particular situation or material to the teachings of the invention without departing from the essential scope thereof. Therefore, it is intended that the invention not be limited to the particular embodiment disclosed as the best mode contemplated for carrying out this invention, but that the invention will include all embodiments falling within the scope of the appended claims.

What is claimed is:

1. A method of forming a complementary metal oxide semiconductor (CMOS) device, the method comprising:
forming an oxide layer on sidewalls and a top surface of a patterned gate conductor, and on sidewalls of a gate insulating layer formed on a semiconductor substrate;
forming a first carbon-based layer over the gate conductor, gate insulating layer, and substrate;
etching the first carbon-based layer so as to create a first set of carbon spacers;
forming a second carbon-based layer over the gate conductor, gate insulating layer, substrate, and first set of carbon spacers;
etching the second carbon-based layer so as to create a second set of carbon spacers;
forming silicide contacts on the gate conductor, and on source and drain regions formed in the substrate;
removing the first and second sets of carbon spacers; and
forming a stress-inducing nitride layer over the substrate, silicide contacts, gate conductor, and gate insulating layer.

2. The method of claim 1, wherein the first and second carbon-based layers comprise amorphous carbon.

3. The method of claim 2, further comprising forming source and drain extensions in the substrate following etching the first carbon-based layer and prior to forming the second carbon-based layer.

4. The method of claim 3, further comprising forming the source and drain regions in the substrate following etching the second carbon-based layer.

5. The method of claim 3, wherein the oxide layer is also formed on the substrate.

6. A method of forming a complementary metal oxide semiconductor (CMOS) device, the method comprising:
forming a patterned gate conductor and gate insulating layer on a semiconductor substrate;
forming an oxide layer on sidewalls and a top surface of the gate conductor, on sidewalls of the gate insulating layer, and on the substrate;
depositing a first amorphous carbon layer over the gate conductor, gate insulating layer, and oxide layer;
anisotropically etching the first carbon-based layer so as to create a first set of amorphous carbon spacers;
implanting source and drain extensions in the substrate following the formation of the first set of amorphous carbon spacers;
forming a second amorphous carbon layer over the gate conductor, gate insulating layer, oxide layer, and first set of amorphous carbon spacers;
anisotropically etching the second amorphous carbon layer so as to create a second set of amorphous carbon spacers adjacent the first set of amorphous carbon spacers;
removing remaining exposed portions of the oxide layer from the substrate and the top surface of the gate conductor;
implanting source and drain regions in the substrate;
forming silicide contacts on the gate conductor, and the source and drain regions formed in the substrate;
isotropically etching and removing the first and second sets of amorphous carbon spacers; and
forming a stress-inducing nitride layer over the substrate, silicide contacts, gate conductor, and gate insulating layer.
